(19) United States
(12) Patent Application Publication
(10) Pub. No.: US 2021/0034092 A1
(43) Pub. Date: Feb. 4, 2021

(54) REFERENCE VOLTAGE CIRCUIT

(71) Applicant: ABLIC Inc., Tokyo (JP)

(72) Inventor: Tsutomu TOMIOKA, Tokyo (JP)

(21) Appl. No.: 16/931,005

(22) Filed: Jul. 16, 2020

(30) Foreign Application Priority Data
Jul. 29, 2019 (JP) 2019-138412

(51) Int. Cl. G05F 3/24; G05F 3/26; G05F 3/18

(52) U.S. Cl. CPC G05F 3/242; G05F 3/185; G05F 3/262

(57) ABSTRACT

Provided is a reference voltage circuit including a Zener diode having a cathode connected to a current source via a first node, and an anode connected to a ground point; a first resistor having one end connected to the first node; a second resistor having one end connected to another end of the first resistor; a first diode having an anode connected to another end of the second resistor via a second node, and a cathode connected to the ground point; and a current control circuit configured to generate a control current corresponding to an anode voltage of the first diode so that the current source supplies a reference current corresponding to the control current to the first diode.

### RELATED APPLICATIONS

This application claims priority to Japanese Patent Application No. 2019-138412, filed on Jul. 29, 2019, the entire content of which is incorporated herein by reference.

### BACKGROUND OF THE INVENTION

### 1. Field of the Invention

The present invention relates to a reference voltage circuit.

### 2. Description of the Related Art

Hitherto, a reference voltage circuit has been widely used in an electronic circuit in which the reference voltage circuit generates a reference voltage used as a threshold voltage in a comparator, which compares a given voltage with the threshold voltage.

A configuration including a Zener diode, a diode, and resistors can be employed in the reference voltage circuit because a reference voltage can be generated from a simple configuration (see, for example, Japanese Patent Application Laid-Open No. S49-128250).

In a conventional reference voltage circuit 100 illustrated in FIG. 7, between an output terminal of a constant current source 103 and the ground point, a Zener diode 104 and a series circuit of resistors 107 and 106 and a diode 105 are connected in parallel in which the Zener diode 104 is connected in a reverse direction and the diode 105 is connected in a forward direction.

The reference voltage circuit 100 thereby supplies an output voltage Vout for a reference voltage from a connection point between the resistors 107 and 106.

In the reference voltage circuit 100, the output voltage Vout is given by Equation (A1).

Vout=(R₁₀₆·V_{z}+R₁₀₇·V_{D})/(R₁₀₆+R₁₀₇) (A1)

In Equation (A1) above, V_{z} is a voltage at a cathode of the Zener diode 104, V_{D} is a voltage at an anode of the diode 105, and R₁₀₆ and R₁₀₇ are resistance of the resistors 106 and 107, respectively.

Further, the current I₁₀₅ flowing through the diode 105 is given by Equation (A2).

I₁₀₅=(V_{z}−V_{D})/(R₁₀₆+R₁₀₇) (A2)

In Equation (A2), the voltage V_{z} has a positive temperature coefficient, and the voltage V_{D} has a negative temperature coefficient.

If temperature coefficients of the resistors 106 and 107 are 0 (if the resistors 106 and 107 have no temperature dependence), the current I₁₀₅ has a positive temperature coefficient.

When the current supplied by the constant current source 103 is denoted by I₁₀₃, the current I₁₀₄ flowing through the Zener diode 104 is given by Equation (A3).

I₁₀₄=I₁₀₃−I₁₀₅ (A3)

When the current I₁₀₃ has no temperature dependence, since the current I₁₀₅ has a positive temperature coefficient, the current I₁₀₄ has a negative temperature coefficient.

That is, as the current I₁₀₅ increases in accordance with temperature rise while the current I₁₀₃ does not change, the current I₁₀₄ relatively decreases. Thus, in the case of the reference voltage circuit 100, since the current I₁₀₄ decreases in accordance with the temperature rise, the linearity of the voltage V_{z} with respect to the temperature change cannot be maintained.

To the contrary, even in a case where the current I₁₀₅ increases by the temperature rising, the linearity of the voltage V_{z} with respect to the temperature change can be maintained, and the temperature coefficient of the output voltage Vout can be brought to 0 by increasing the current I₁₀₃ in order to reduce the influence of the negative temperature coefficient of the voltage V_{D}.

However, in order to maintain the linearity of the voltage V_{z}, constant flow of the current I₁₀₃ which is large enough to reduce the influence of the negative temperature coefficient of the voltage V_{D} should be supplied through the Zener diode 104 as a bias current, making the reduction of the power consumption of the reference voltage circuit difficult.

### SUMMARY OF THE INVENTION

The present invention has an object to provide a reference voltage circuit capable of maintaining a linearity of a temperature dependence of the voltage applied to the cathode of the Zener diode without increasing the current flowing from a constant current source to the Zener diode, and thus capable of saving power through reduction of power consumption.

According to an embodiment of the present invention, a reference voltage circuit includes a Zeller diode having a cathode connected to a current source via a first node, and an anode connected to a ground point; a first resistor having one end connected to the first node; a second resistor having one end connected to another end of the first resistor; a first diode having an anode connected to another end of the second resistor via a second node, and a cathode connected to the ground point; and a current control circuit which generates a control current corresponding to an anode voltage of the first diode so that the current source to supplies a reference current corresponding to the control current to the first diode.

According to the reference voltage circuit of the present invention, the reference voltage circuit capable of maintaining the linearity of the temperature dependence of the voltage applied to the cathode of the Zener diode without increasing the current flowing from the constant current source to the Zener diode, and thus capable of saving power through reduction of power consumption can be provided.

### BRIEF DESCRIPTION OF THE DRAWINGS

FIG. 1 is a circuit diagram illustrating a configuration example of a reference voltage circuit according to a first embodiment of the present invention.

FIG. 2 is a circuit diagram illustrating an example of a V/I conversion element.

FIG. 3 is a circuit diagram illustrating a modification example of the reference voltage circuit according to the first embodiment.

FIG. 4 is a circuit diagram illustrating a configuration example of a reference voltage circuit according to a second embodiment of the present invention.

FIG. 5 is a circuit diagram illustrating a configuration example of a reference voltage circuit according to a third embodiment of the present invention.

FIG. 6 is a circuit diagram illustrating a configuration example of a reference voltage circuit according to a fourth embodiment of the present invention.

FIG. 7 is a circuit diagram illustrating a conventional reference voltage circuit.

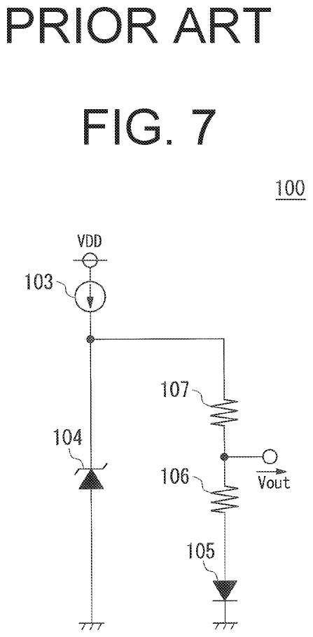

### DETAILED DESCRIPTION OF THE PREFERRED EMBODIMENTS

Now, description is given of embodiments of the present invention with reference to the drawings.

### First Embodiment

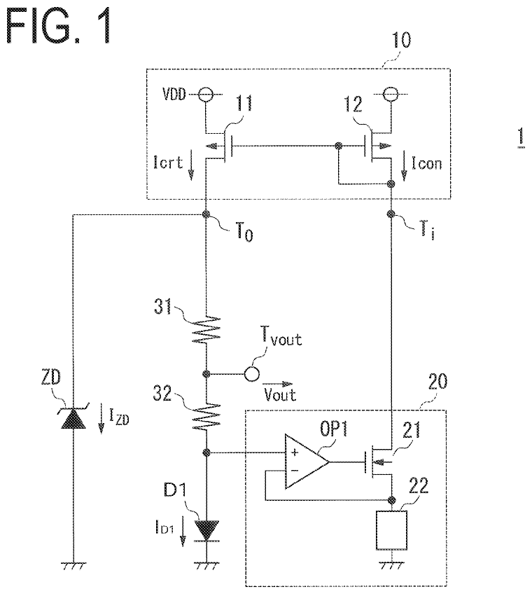

FIG. 1 is a circuit diagram illustrating a configuration example of a reference voltage circuit according to the first embodiment of the present invention.

A reference voltage circuit 1 includes a current mirror circuit 10, a current control circuit 20, a resistor 31 (first resistor), a resistor 32 (second resistor), a Zener diode ZD, and a diode D1.

The current mirror circuit 10 includes p-channel transistors 11 and 12. A drain of the transistor 11 is connected to an output terminal To, and a drain of the transistor 12 is connected to an input terminal Ti.

The current control circuit 20 is a current source in the reference voltage circuit 1, and includes an error amplifier circuit OP1, a transistor 21, and a V/I conversion element 22.

The Zener diode ZD has a cathode connected to the output terminal To of the current mirror circuit 10, and an anode connected to the ground point.

The resistor 31 has one end connected to the cathode of the Zener diode ZD, and the other end connected to one end of the resistor 32 and an output terminal Tvout. The other end of the resistor 32 is connected to the anode of the diode D1. The cathode of the diode D1 is connected to the ground point.

The transistor 21 is an n-channel transistor. The transistor 21 includes a drain connected to the input terminal Ti of the current mirror circuit 10, a gate connected to an output terminal of the error amplifier circuit OP1, and a source connected to one end of the V/I conversion element 22.

The error amplifier circuit OP1 includes a non-inverting input terminal connected to the anode of the diode D1, and an inverting input terminal connected to the one end of the V/I conversion element 22.

The other end of the V/I conversion element 22 is connected to the ground point to convert a voltage V_{D} of the diode D1 into a control current I_{con}.

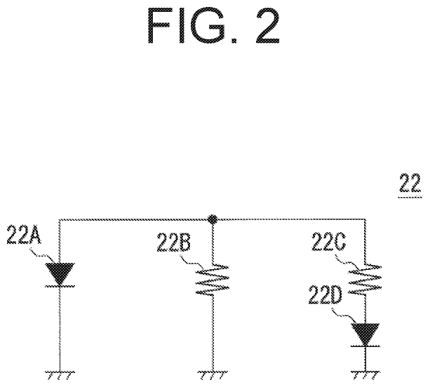

FIG. 2 is a circuit diagram illustrating an example of the V/I conversion element. In FIG. 2, the V/I conversion element 22 includes a diode 22A, a resistor 22B, a resistor 22C, and a diode 22D.

Between the one end and the other end of the V/I conversion element 22, the diode 22A, the resistor 22B, and a series circuit including the resistor 22C and the diode 22D are connected in parallel. In this case, the diodes 22A and 22D are connected in a forward direction along the one end to the other end of the V/I conversion element 22.

In the reference voltage circuit 1, when the sources of the transistors 11 and 12 are applied with a power supply voltage VDD, the output voltage Vout is supplied from the output terminal Tvout.

At this time, a current I_{ZD} flowing through the Zener diode ZD generates a voltage V_{Z} as a reverse voltage at the cathode of the Zener diode ZD. Further, a current I_{D1} flowing through the diode D1 generates a voltage V_{D} as a forward voltage at the anode of the diode D1.

The output voltage Vout is determined in accordance with the voltage V_{Z}, the voltage V_{D}, and a voltage dividing ratio of the resistors 31 and 32. In Equation (1) below, the resistance of the resistors 31 and 32 are R₃₁ and R₃₂, respectively.

Vout=(R₃₂·V_{Z}+R₃₁·V_{D})/(R₃₁+R₃₂) (1)

Then, the voltage V_{Z} of the Zener diode ZD is adjusted to have a positive temperature coefficient so as to balance with the negative temperature coefficient of the voltage V_{D} of the diode D1 so that the output voltage Vout of the reference voltage circuit 1 has no temperature dependence temperature coefficient is zero). The resistance R₃₁ and R₃₂ of the resistors 31 and 32 are thus set to satisfy Equation (2) below in a case where the current I_{ZD} flowing through the Zener diode ZD is supplied as a bias current.

R₃₂·(dV_{Z}/dT)+R₃₁·(dV_{D}/dT)=0 (2)

In Equation (2) above, (dV_{Z}/dT) represents an amount of change of the cathode voltage V_{Z} per unit temperature change and has a positive temperature coefficient. Further, (dV_{D}/dT) represents an amount of change of the voltage V_{D} per unit temperature change and has a negative temperature coefficient.

The current control circuit 20 functions as a V/I converter circuit which converts the voltage V_{D} of the diode D1 into a corresponding control current I_{con}.

That is, the error amplifier circuit OP1 causes the transistor 21 to perform negative feedback processing so that the voltage drop of the V/I conversion element 22 becomes equal to the voltage V_{D}. The control current I_{con} corresponding to the voltage V_{D} thus flows through the V/I conversion element 22 from the input terminal Ti of the current mirror circuit 10.

The control current I_{con} is a combined current of currents flowing through the diode 22A, the resistor 22B, and the series connection of the resistor 22C and the diode 22D.

In this case, through the diode 22A, there flows a current I_{22A} which is determined by the area ratio (area ratio of P/N junction) between the diode 22A and the diode D1 and is proportional to the current I_{D1}. The voltage drop of the diode 22A has a negative temperature coefficient.

Further, through the resistor 22B, a current I_{22B} (=V_{D}/R_{22B}) proportional to the voltage V_{D} of the diode D1 flows. R_{22B} is a resistance of the resistor 22B. The current I_{22B} has a negative temperature coefficient.

Through the resistor 22C and the diode 22D, a current I_{22C} (=ΔV_{D}/R_{22C}) proportional to the difference voltage ΔV_{D} between the anode voltage of the diode D1 and the anode voltage of the diode 22D flows. R_{22C} is a resistance of the resistor 22C. The difference voltage ΔV_{D} has a positive temperature coefficient.

In response to an input of the control current I_{con} to the input terminal Ti from the current control circuit 20, the current mirror circuit 10 supplies a reference current I_{crt} to the Zener diode ZD and the diode D1 from the output terminal To in accordance with the predetermined mirror ratio. For example, in a case where the mirror ratio of the output current with respect to the input current is K, the reference current I_{crt} is given by Equation (3) below.

I_{crt}=K·(I_{22A}+I_{22B}+I_{22C}) (3)

For example, in a case where the area ratio between the diode D1 and the diode 22A is 1:1, the area ratio between the diode at and the diode 22D is 1:N (>1, for example, 2 or more), and K=1 holds, the reference current I_{crt} is given by Equation (4) below.

I_{crt}=I_{22A}+V_{D}/R_{22B}+ΔV_{D}/R_{22C} (4)

where I_{22A}=I_{D1} holds.

In Equation (4), the first term I_{22A} is a current flowing through the diode 22A having a characteristic similar to that of the diode D1 and is the same as the current I_{D1} flowing through the diode D1. The current I_{D1} is supplied from the output terminal To of the current mirror circuit 10 to the diode D1 as a feedback corresponding to the voltage V_{D}.

Thus, the second term V_{D}/R_{22B} and the third term ΔV_{D}/R_{22C} are currents supplied from the output terminal To of the current mirror circuit 10 to the Zener diode ZD.

The current I_{ZD} flowing through the Zener diode ZD is given by Equation (5) which is obtained by excluding the first term from Equation (4).

I_{ZD}=V_{D}/R_{22B}+ΔV_{D}/R_{22C} (5)

As is understood from Equation (5) above, the first term and the second term represent currents flowing through the resistor 22B and the series circuit of the resistor 22C and the diode 22D, respectively, and are thus not affected by the current I_{D1} flowing through the diode D1.

Further, in a case where the temperature coefficients of the resistors 22B and 22C are zero, the temperature coefficient of the current V_{D}/R_{22B} is negative because the voltage V_{D} has a negative temperature coefficient, and the temperature coefficient of the current ΔV_{D}/R_{22C} is positive because the difference voltage ΔV_{D} has a positive temperature coefficient. Thus, through adjustment of the resistance R_{22B} of the resistor 22B and the resistance R_{22C} of the resistor 22C, the temperature characteristic of the current I_{ZD} flowing through the Zener diode ZD can be arbitrarily adjusted to be positive or negative.

As described above, the reference voltage circuit 1 generates the control current I_{con} by combining the current corresponding to the voltage V_{D} and the current corresponding to the current I_{ZD} flowing through the Zener diode ZD, supplies the reference current I_{crt} from the current mirror circuit 10 in accordance with the control current I_{con}, and adjusts the currents I_{D1} and I_{ZD} in accordance with the temperature change.

As described above, in accordance with variation that is based on the temperature dependence of each of the voltage V_{D} and the voltage V_{Z}, the current I_{D1} which compensates this variation is supplied to flow through the diode D1, and the current I_{ZD} is supplied to flow through the Zener diode ZD, permitting arbitrary control of the voltage V_{Z}.

Since the reference voltage circuit 1 is capable of supplying the current I_{ZD} in response to the temperature change with adjustment to the minimum necessary current amount, the reference voltage circuit 1 is thus capable of saving power while maintaining the linearity of the temperature dependence of the voltage V_{Z} applied to the cathode of the Zener diode ZD.

The reference voltage circuit 1 may include a start-up circuit (not shown) to apply a predetermined pulse current to the resistor 31 at the time of start-up.

Further, the V/I conversion element 22 has been described as a configuration including the diode 22A, the resistor 22B, the resistor 22C, and the diode 22D, but the V/I conversion element 22 may be a configuration including any one of the diode 22A, the resistor 22B, and the series circuit of the resistor 22C and the diode 22D, or a combination thereof. In the case of such configuration, in order to maintain the linearity of the cathode voltage V_{Z}, the mirror ratio of the current mirror circuit 10, the area ratios of the diodes 22A and 22D, and the resistances of the resistors 22B and 22C are adjusted, and the control current I_{con} is generated from the voltage V_{D} so that the sum of the currents I_{D1} and I_{ZD} become the current I_{crt} that is adjusted as appropriate in accordance with the temperature change.

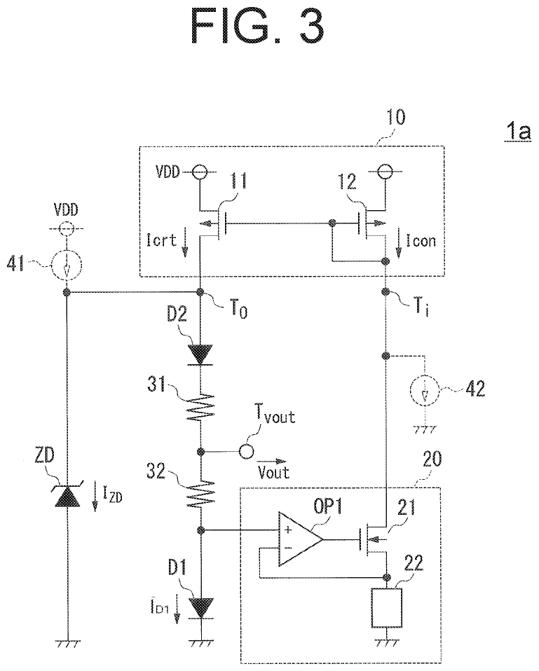

FIG. 3 is a circuit diagram illustrating a modification example of the reference voltage circuit according to the first embodiment. Configurations and operations different from those of the reference voltage circuit 1 of FIG. 1 are described below.

In a reference voltage circuit 1a a diode D2 is added to the configuration of FIG. 1. The diode D2 includes an anode connected to the output terminal To of the current mirror circuit 10, and a cathode connected to the one end of the resistor 31. In a case where the voltage drop of the diode D2 is V_{D2}, the output voltage Vout is given by Equation (6) below.

Vout=(R₃₂·(i V_{Z}−V_{D2})+R₃₁·V_{D})/(R₃₁+R₃₂) (6)

Through addition of the diode D2, the voltage at the one end of the resistor 31 connected to the cathode of the diode D2 has a positive temperature coefficient because the anode voltage of the diode D2 has a negative temperature coefficient. The voltage at the one end of the resistor 31 thus changes in accordance with the temperature change.

Since the voltage at the one end of the resistor 31 has a positive temperature coefficient, in order to eliminate the temperature dependence of the output voltage Vout, the resistance R₃₁ of the resistor 31 is increased, as is understood from Equation (6). As a result, the voltage drop of the resistor 31 increases, and the output voltage Vout decreases.

Thus, as compared to the configuration of FIG. 1, in a case where a lower output voltage Vout is required, as illustrated in FIG. 3, the lower output voltage Vout can be easily obtained by adding the diode D2.

Further, as illustrated in FIG. 3, there may be employed a configuration in which any one of constant current sources 41 and 42 is added.

For example, by the addition of the constant current source 41 to the cathode of the Zener diode ZD, the Zener diode ZD is supplied with the current I_{ZD} from the constant current source 41. As a result, the current mirror circuit 10 supplies the reference current I_{crt} as the current I_{D1} flowing through the diode D1. In this case, the current I_{ZD} flowing through the Zener diode ZD is not affected by the voltage V_{D}, and the current control circuit 20 compensates only the current I_{D1} flowing through the diode D1 in accordance with the temperature change.

The V/I conversion element 22 thus has, for example, a configuration including only the diode 22A illustrated in FIG. 2, and is configured to apply the voltage V_{D} to the inverting input terminal of the error amplifier circuit OP1 in response to the voltage drop to that of the diode D1.

Further, also in a case where the constant current source 42 is added to the input terminal Ti of the current mirror circuit 10, similarly to the above-mentioned case in which the constant current source 41 is added, the current control circuit 20 compensates only the current I_{D1} flowing through the diode D1.

### Second Embodiment

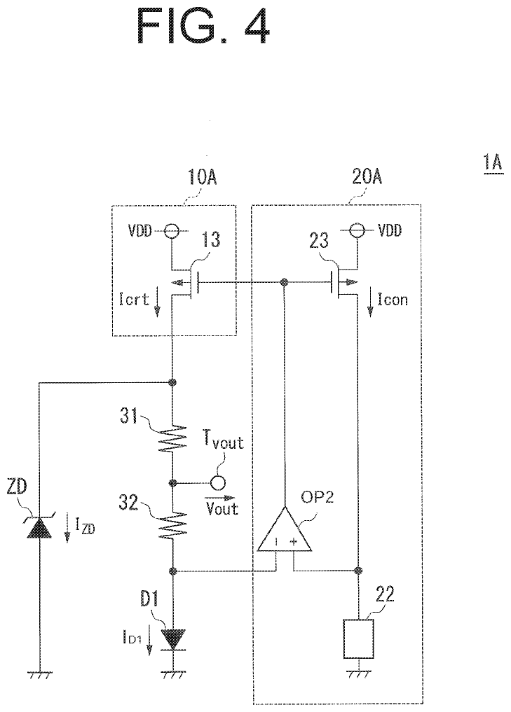

FIG. 4 is a circuit diagram illustrating a configuration example of a reference voltage circuit according to the second embodiment of the present invention.

A reference voltage circuit 1A includes a current source 10A, a current control circuit 20A, resistors 31 and 32, a Zener diode ZD, and a diode D1.

The current source 10A includes a p-channel transistor 13.

The current control circuit 20A includes an error amplifier circuit OP2, a V/I conversion element 22, and a transistor 23.

The transistor 13 includes a source to which a power supply voltage VDD is applied, a gate connected to the output terminal of the error amplifier circuit OP2 and the gate of the transistor 23, and a drain connected to the cathode of the Zener diode ZD and one end of the resistor 31.

The transistor 23 is a p-channel transistor. The transistor 23 includes a source to which the power supply voltage VDD is applied, and a drain connected to one end of the V/I conversion element 22 and the non-inverting input terminal of the error amplifier circuit OP2.

The V/I conversion element 22 has another end connected to the ground point.

The resistor 31 has another end connected to the output terminal Tvout and one end of the resistor 32.

The resistor 32 has another end connected to the anode of the diode D1 and the inverting input terminal of the error amplifier circuit OP2.

The anode of the Zener diode ZD is connected to the ground point.

The cathode of the diode D1 is connected to the ground point.

The current control circuit 20A functions as a V/I converter circuit to convert a voltage V_{D} of the diode D1 into a control current I_{con} corresponding to the voltage V_{D}.

The voltage drop of the V/I conversion element 22 is substantially equal to the voltage V_{D} of the diode D1 due to the negative feedback of the transistor 23 because the error amplifier circuit OP2 and the transistor 23 form a voltage follower.

Thus, through the V/I conversion element 22, the control current I_{con} flows through the transistor 23 as a current corresponding to the voltage V_{D} of the diode D1.

A drain current corresponding to the aspect ratio flows through each of the transistors 13 and 23 because the transistors 13 and 23 have the same gate voltage. As a result, a reference current I_{crt} corresponding to the control current I_{con} flowing through the V/I conversion element 22 flows through the transistor 13.

As described above, similarly to the first embodiment, the reference voltage circuit according to the second embodiment generates the control current I_{con} from the anode voltage V_{D} varying depending on the temperature change, to thereby supply, in accordance with the control current I_{con}, the reference current I_{crt} which is a combined current of the current I_{D1} flowing through the diode D1 and the current I_{ZD} flowing through the Zener diode ZD, from the transistor 13.

Since the reference voltage circuit according to the second embodiment is capable of supplying the current I_{ZD} in accordance with the temperature change with the current I_{ZD} which is adjusted to the minimum necessary current amount, the reference voltage circuit is thus capable of saving power while maintaining the linearity of the temperature dependence of the voltage V_{Z} which is applied to the cathode of the Zener diode ZD.

### Third Embodiment

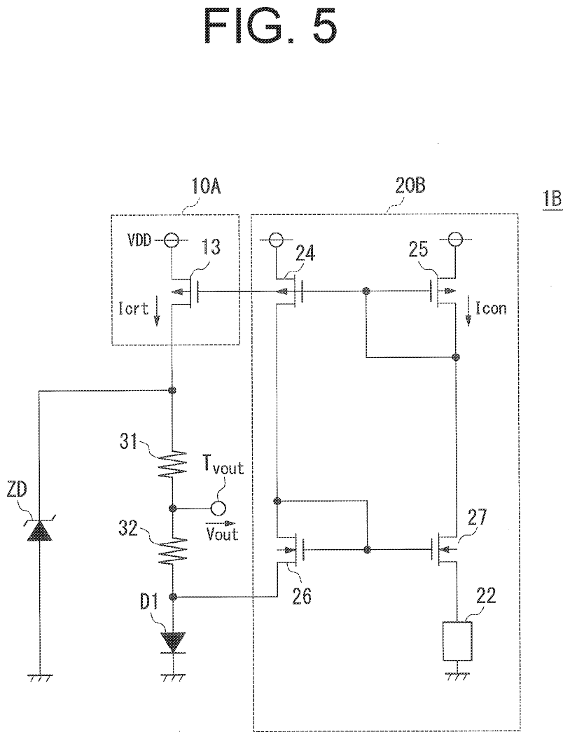

FIG. 5 is a circuit diagram illustrating a configuration example of a reference voltage circuit according to the third embodiment of the present invention.

A reference voltage circuit 1B has a configuration similar to that of the second embodiment except that the reference voltage circuit 1B includes a current control circuit 20B.

The current control circuit 20B includes p-channel transistors 24 and 25, n-channel transistors 26 and 27, and a V/I conversion element 22.

The transistor 24 includes a source to which the power supply voltage VDD is applied, a gate connected to the gate and the drain of the transistor 25, and a drain connected to the drain and the gate of the transistor 26.

The transistor 25 includes a source to which the power supply voltage VDD is applied, and the drain connected to the drain of the transistor 27.

The transistor 26 includes the gate connected to the gate of the transistor 27, and a source connected to the anode of the diode D1.

The transistor 27 includes a source connected to the ground point through the V/I conversion element 22.

The current control circuit 20B functions as a V/I converter circuit to convert a voltage V_{D} of the diode D1 into a control current I_{con} corresponding to the voltage V_{D}.

The transistors 24 and 25 form a current mirror, and the current corresponding to a mirror ratio between the transistors 24 and 25 flows through each of the transistors 26 and 27 so as to determine the source voltage of the transistor 27.

For example, in a case where the mirror ratio between the transistors 24 and 25 is 1:1, and the transistors 26 and 27 have the same aspect ratio, the same drain current flows through each of the transistors 26 and 27. The source voltage (voltage V_{D} ) of the transistor 26 thereby become equal the source voltage of the transistor 27. That is, the voltage drop of the V/I conversion element 22 becomes substantially equal to the voltage V_{D}.

Since the control current I_{con} corresponding to the voltage V_{D} flows through the V/I conversion element 22 via the transistor 25, a reference current I_{crt} corresponding to the mirror ratio with respect to the control current I_{con} flowing through the V/I conversion element 22 flows through the transistor 13 forming a current mirror with the transistor 25.

As described above, the reference voltage circuit 1B generates the control current I_{con} based on the voltage V_{D} varying depending on the temperature change, to thereby supply, in accordance with the control current I_{con}, the reference current I_{crt} which is a combined current of the current I_{D1} flowing through the diode D1 and the current I_{ZD} flowing through the Zener diode ZD, from the transistor 13.

Since the reference voltage circuit 1B is capable of supplying the current I_{ZD} in accordance with the temperature change with the current I_{ZD} which is adjusted to the minimum necessary current amount, the reference voltage circuit 1B is thus capable of saving power while maintaining the linearity of the temperature dependence of the voltage V_{Z} applied to the cathode of the Zener diode ZD.

### Fourth Embodiment

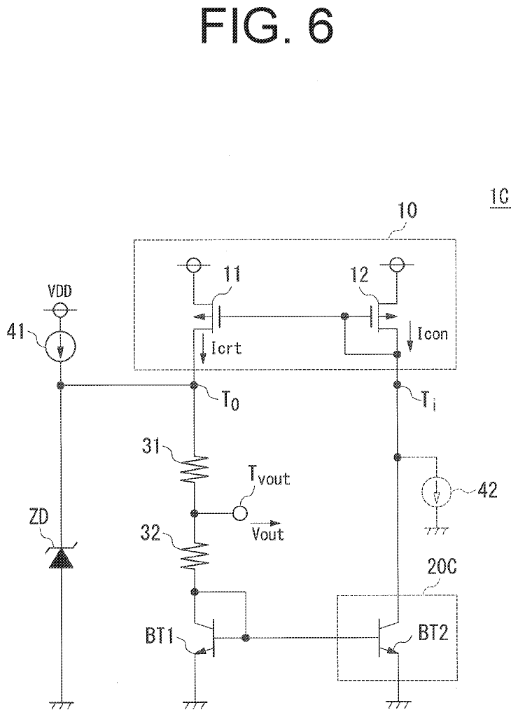

FIG. 6 is a circuit diagram illustrating a configuration example of a reference voltage circuit according to the fourth embodiment of the present invention.

A reference voltage circuit 1C has a configuration similar to that of the first embodiment except that the reference voltage circuit 1C includes a current control circuit 20C, a bipolar transistor BT1, and a constant current source 41.

The current control circuit 20C includes a bipolar transistor BT2.

The bipolar transistors BT1 and BT2 are npn-type bipolar transistors and form a current mirror.

The bipolar transistor BT1 includes a collector connected to a base of the bipolar transistor BT1 and the other end of the resistor 32, and an emitter connected to the ground point. That is, the bipolar transistor BT1 corresponds to the diode D1 in the first embodiment.

The bipolar transistor BT2 includes a collector connected to the input terminal Ti of the current mirror circuit 10, a base connected to the base of the bipolar transistor BT1, and an emitter connected to the ground point. In this case, the base or the emitter of the bipolar transistor BT2 corresponds to the diode 22A of the V/I conversion element 22 in the first embodiment and has a diode characteristic similar to that of the base or the emitter of the bipolar transistor BT1.

In the bipolar transistor BT1, when the voltage V_{D} is applied to the base, the base current flows corresponding to the voltage V_{D}, and a collector current (current I_{D1}) corresponding to the base current flows.

Through the bipolar transistor BT2, a collector current flows based on the mirror ratio between the bipolar transistor BT2 and the bipolar transistor BT1.

The collector current of the bipolar transistor BT2 is a control current I_{con} flowing in accordance with the voltage V_{D} and is supplied to the input terminal Ti of the current mirror circuit 10.

The current mirror circuit 10 thereby supplies the reference current I_{crt} corresponding to the mirror ratio from the output terminal To.

Here, when the mirror ratio of the current mirror circuit 10 is 1:1, and the mirror ratio between the bipolar transistors BT1 and BT2 is 1:1, the reference current I_{crt} supplied from the output terminal of the current mirror circuit 10 becomes substantially equal to the current I_{D1}.

Since the current I_{ZD} flowing through the Zener diode ZD is thus supplied from the constant current source 41 and is not affected by the voltage V_{D}, the current control circuit 20C compensates only the current I_{D1} flowing through the diode D1 at the bipolar transistor BT1.

Further, also in a case where the constant current source 42 is added to the input terminal Ti of the current mirror circuit 10, similarly to the above-mentioned case in which the constant current source 41 is added, the current control circuit 20C compensates only the current I_{D1} flowing through the bipolar transistor BT1 (corresponding to the diode D1) in which the collector and the base are connected.

As described above, the reference voltage circuit 1C is configured to generate the control current I_{con} corresponding to the voltage V_{D} in the diode connection of the bipolar transistor BT1, to thereby cause, in accordance with the control current I_{con}, the reference current I_{crt} to flow from the transistor 13 to adjust the current I_{D1} in accordance with the temperature change.

Thus, since the reference voltage circuit 1C is capable of supplying the current I_{ZD} in accordance with the temperature change with the current I_{ZD} being adjusted to the minimum necessary current amount, the reference voltage circuit 1C is capable of saving power while maintaining the linearity of the temperature dependence of the voltage V_{Z} to be applied to the cathode of the Zener diode ZD.

The embodiments of the present invention have been described above in detail with reference to the drawings. However, specific configurations of the present invention are not limited to the embodiments and encompass designs, modifications, and the like without departing from the gist of the present invention.

What is claimed is:

1. A reference voltage circuit, comprising:
a Zener diode having a cathode connected to a current source via a first node, and an anode connected to a ground point;
a first resistor having one end connected to the first node;
a second resistor having one end connected to another end of the first resistor;
a first diode having an anode connected to another end of the second resistor via a second node, and a cathode connected to the ground point; and
a current control circuit configured to generate a control current corresponding to an anode voltage of the first diode so that the current source supplies a reference current corresponding to the control current to the first diode.

2. The reference voltage circuit according to claim 1,
wherein the current source comprises a first current mirror circuit configured to receive the control current as an input current and supply the reference current as an output current, and
wherein the current control circuit comprises a V/I conversion element configured to convert the anode voltage into the control current.

3. The reference voltage circuit according to claim 2, wherein the current control circuit comprises:
a first error amplifier circuit having a non-inverting input terminal connected to the second node, and an inverting input terminal connected to one end of the V/I conversion element; and
a first transistor of an n-channel type having a drain connected to an input terminal of the first current mirror circuit, a gate connected to an output terminal of the first error amplifier circuit, and a source connected to the one end of the V/I conversion element.

4. The reference voltage circuit according to claim 1,
wherein the current source comprises a second transistor of a p-channel type having a source connected to a power supply, and a drain connected to the first node, and
wherein the current control circuit is configured to control the second transistor so that the reference current corresponding to the control current flows.

5. The reference voltage circuit according to claim 4, wherein the current control circuit comprises:
a third transistor of a p-channel type having a source connected to the power supply;
a second error amplifier circuit having an inverting input terminal connected to the second node, a non-inverting input terminal connected to a drain of the third transistor, and an output terminal connected to a gate of the second transistor and a gate of the third transistor; and
a V/I conversion element connected between the non-inverting input terminal and the ground point, the V/I conversion element having substantially a same characteristic as a characteristic of the first diode.

6. The reference voltage circuit according to claim 4, wherein the current control circuit comprises:
a second current mirror circuit;
a fourth transistor of an n-channel type having a drain connected to an input terminal of the second current mirror circuit;
a fifth transistor of an n-channel type having a drain and a gate connected to an output terminal of the second current mirror circuit and a gate of the fourth transistor, and a source connected to the second node; and
a V/I conversion element connected between a source of the fourth transistor and the ground point, the V/I conversion element having substantially a same characteristic as a characteristic of the first diode.

7. The reference voltage circuit according to claim 1, further comprising a fourth diode connected in a forward direction between the first node and the first resistor.

8. The reference voltage circuit according to claim 2, further comprising a fourth diode connected in a forward direction between the first node and the first resistor.

9. The reference voltage circuit according to claim 4, further comprising a fourth diode connected in a forward direction between the first node and the first resistor.

10. The reference voltage circuit according to claim 3, wherein the V/I conversion element comprises a second diode having substantially a same characteristic as a characteristic of the first diode.

11. The reference voltage circuit according to claim 3, wherein the V/I conversion element comprises any one of a second diode, a third resistor, and a series circuit in which a fourth resistor and a third diode are connected in series, or a combination thereof, the combination forming a parallel circuit.

12. The reference voltage circuit according to claim 3, further comprising a fourth diode connected in a forward direction between the first node and the first resistor.

13. The reference voltage circuit according to claim 5, wherein the V/I conversion element comprises a second diode having substantially a same characteristic as a characteristic of the first diode.

14. The reference voltage circuit according to claim 5, wherein the V/I conversion element comprises any one of a second diode, a third resistor, and a series circuit in which a fourth resistor and a third diode are connected in series, or a combination thereof, the combination forming a parallel circuit.

15. The reference voltage circuit according to claim 5, further comprising a fourth diode connected in a forward direction between the first node and the first resistor.

16. The reference voltage circuit according to claim 6, wherein the V/I conversion element comprises a second diode having substantially a same characteristic as a characteristic of the first diode.

17. The reference voltage circuit according to claim 6, wherein the V/I conversion element comprises any one of a second diode, a third resistor, and a series circuit in which a fourth resistor and a third diode are connected in series, or a combination thereof, the combination forming a parallel circuit.

18. The reference voltage circuit according to claim 6, further comprising a fourth diode connected in a forward direction between the first node and the first resistor.

19. The reference voltage circuit according to claim 1,
wherein the current source comprises:
a constant current source configured to supply a current flowing through the Zener diode; and
a third current mirror circuit having an output terminal connected to the first node,
wherein the first diode is formed of a first bipolar transistor of an npn type having a collector connected to a base, and an emitter connected to the ground point,
wherein the current control circuit is formed of a second bipolar transistor of an npn type having a collector connected to an input terminal of the third current mirror circuit, a base connected to the collector and the base of the first bipolar transistor, and an emitter connected to the ground point, and
wherein the third current mirror circuit is configured to receive the control current as an input current and supply the reference current as an output current.

20. The reference voltage circuit according to claim 19, wherein the first bipolar transistor has substantially a same base-emitter diode characteristic as a base-emitter diode characteristic of the second bipolar transistor.
